(19) United States
(12) Patent Application Publication
(10) Pub. No.: US 2025/0031529 A1
(43) Pub. Date: Jan. 23, 2025

(54) LIGHT EMITTING DISPLAY DEVICE

(71) Applicant: LG Display Co., Ltd., Seoul (KR)

(72) Inventors: Hee Tae LIM, Paju-si (KR); Woo Young LEE, Paju-si (KR); Sung Min JO, Paju-si (KR); Myeong Seon CHO, Paju-si (KR)

(21) Appl. No.: 18/773,160

(22) Filed: Jul. 15, 2024

(30) Foreign Application Priority Data
Jul. 17, 2023 (KR) 10-2023-0092549

(51) Int. Cl. H10K 59/122

(52) U.S. Cl. CPC H10K 59/122

(57) ABSTRACT

Disclosed is a light-emitting display device including a light-transmitting portion between a plurality of light-emitting portions, a first bank exposing each of the light-emitting portions and the light-transmitting portion, and an intermediate layer on the plurality of light-emitting portions and the first bank. The first bank has a first side surface adjacent to the light-emitting portion and a second side surface adjacent to the light-transmitting portion, and the second side surface has a reverse taper shape.

### CROSS-REFERENCE TO RELATED APPLICATION(S)

This application claims the benefit of Korean Patent Application No. 10-2023-0092549, filed on Jul. 17, 2023, which is hereby incorporated by reference as if fully set forth herein.

### BACKGROUND

### Technical Field

The present disclosure relates to a light-emitting display device, and more particularly, to a light-emitting display device that is capable of preventing leakage current from flowing to adjacent sub-pixels.

### Description of the Related Art

With the advent of the information society, displays for visually expressing electrical information signals have developed rapidly. In response to this, research is underway on development of various display devices with excellent performance such as slimness, reduced weight, and lower power consumption.

There among, a light-emitting display device includes a light-emitting element spontaneously capable of emitting light and thus does not require a separate light source used in a non-light-emitting element, thus realizing reduced weight and thickness.

The light-emitting element includes an intermediate layer between a first electrode and a second electrode, and the intermediate layer emits light when an electric field is applied between the first and second electrodes.

### BRIEF SUMMARY

The light-emitting display device including the light-emitting element in the related art may have a problem in which at least one of a plurality of sub-pixels emits light due to leakage current flowing from adjacent sub-pixels. Accordingly, the various embodiments of disclosure is directed to a light-emitting display device that substantially obviates one or more problems due to the limitations and disadvantages of the related art, including the above-identified problem.

Various embodiments of the present disclosure provide a light-emitting display device that is capable of preventing light emission in some of the sub-pixels PXL due to leakage current flowing from adjacent sub-pixels.

Various embodiments of the present disclosure provide a light-emitting display device that is capable of preventing light emission in some of the sub-pixels PXL due to leakage current flowing from adjacent sub-pixels while preventing deterioration of the light-emitting element.

Additional advantages, technical benefits, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

The light-emitting display device of the present disclosure can minimize contact between respective light-emitting portions of a plurality of sub-pixels through arrangement of respective light-transmitting portions of the sub-pixels, thereby maximizing a path through which leakage current flows between adjacent sub-pixels.

In addition, the light-emitting display device of the present disclosure includes an undercut area adjacent to the light-transmitting portions, thereby blocking a path through which leakage current flows between adjacent sub-pixels and at the same time, uniformly depositing an intermediate layer on the light-emitting portions.

In addition, the light-emitting display device of the present disclosure includes a nucleation inhibition layer in the light-transmitting portion, thereby greatly reducing the thickness of the intermediate layer deposited on the nucleation inhibition layer and preventing leakage current from flowing through the intermediate layer with high resistance on the light-transmitting portion.

Accordingly, the light-emitting display device according to an embodiment of the present disclosure includes a light-transmitting portion between a plurality of light-emitting portions, a first bank exposing each of the light-emitting portions and the light-transmitting portion, and an intermediate layer on the plurality of light-emitting portions and the first bank, wherein the first bank has a first side surface adjacent to the light-emitting portion and a second side surface adjacent to the light-transmitting portion, and the second side surface has a negative taper shape.

It is to be understood that both the foregoing general description and the following detailed description of the disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a plan view illustrating a configuration of a light-emitting display device according to a first embodiment of the present disclosure;

FIG. 2 is a cross-sectional view taken along line I-I′ of FIG. 1;

FIG. 3 is a cross-sectional view taken along line I-I′ of FIG. 1 according to a second embodiment of the present disclosure;

FIG. 4 is a cross-sectional view taken along line I-I′ of FIG. 1 according to a third embodiment of the present disclosure;

FIG. 5 is a cross-sectional view taken along line I-I′ of FIG. 1 according to a fourth embodiment of the present disclosure;

FIG. 6 is a cross-sectional view illustrating a light-emitting display device according to a fifth embodiment of the present disclosure;

FIG. 7 is a cross-sectional view illustrating a light-emitting display device according to a sixth embodiment of the present disclosure;

FIG. 8 is a plan view illustrating a light-emitting display device according to a seventh embodiment of the present disclosure; and

FIG. 9 is a cross-sectional view taken along line II-II′ of FIG. 8.

### DETAILED DESCRIPTION

The advantages and features of the present disclosure and methods of accomplishing the same will be clearly understood from the following preferred embodiments with reference to the attached drawings. However, the present disclosure is not limited to the embodiments, and may be embodied in different forms. The embodiments are suggested only to offer a thorough and complete understanding of the disclosed context and to sufficiently inform those skilled in the art of the technical concept of the present disclosure and embodiments of the present disclosure are only defined by the scope of the claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Wherever possible, the same reference numbers will be used throughout the drawings to refer to the same or like parts. In the following description, detailed descriptions of technologies or configurations related to the present disclosure may be omitted so as to avoid unnecessarily obscuring the subject matter of the present disclosure.

When terms such as “including,” “having,” and “comprising” are used throughout the disclosure, an additional component may be present, unless “only” is used. A component described in a singular form encompasses a plurality thereof unless particularly stated otherwise.

The components included in the embodiments of the present disclosure should be interpreted to include an error range, even if there is no additional particular description thereof.

In describing the variety of embodiments of the present disclosure, when terms describing positional relationships such as “on,” “above,” “under” and “next to” are used, at least one intervening element may be present between the two elements, unless “immediately” or “directly” is also used.

In describing the variety of embodiments of the present disclosure, when terms related to temporal relationships, such as “after,” “subsequently,” “next,” and “before,” are used, the non-continuous case may be included, unless “immediately” or “directly” is also used.

In describing the variety of embodiments of the present disclosure, terms such as “first” and “second” may be used to describe a variety of components, but these terms only aim to distinguish the same or similar components from one another. Accordingly, throughout the disclosure, a “first” component may be the same as a “second” component within the technical concept of the present disclosure, unless specifically mentioned otherwise.

The terms “first horizontal axis direction,” “second horizontal axis direction,” and “vertical axis direction” should not be interpreted as only geometric relationships in which the relationship between each other is vertical, and as having a broader range of direction as long as the configuration of the present disclosure can serve functionally.

The term “at least one” should be understood to include all possible combinations of one or more related items. For example, “at least one of the first, second, and third items” means each of the first, second, or third items, as well as any combination of two or more of the first, second, and third items.

Features of various embodiments of the present disclosure may be partially or completely coupled to or combined with each other, and may be variously inter-operated with each other and driven technically. The embodiments of the present disclosure may be carried out independently from each other, or may be carried out together in an interrelated manner.

In adding reference numerals to components in each drawing, identical components may have the same reference numerals as much as possible even if they are shown in different drawings. In addition, the scale of the components shown in the attached drawings has a different scale from the actual scale for convenience of explanation and is thus not limited to the scale shown in the drawings.

Hereinafter, a preferred example of a light-emitting display device according to an embodiment of the present disclosure will be described in detail with reference to the annexed drawings.

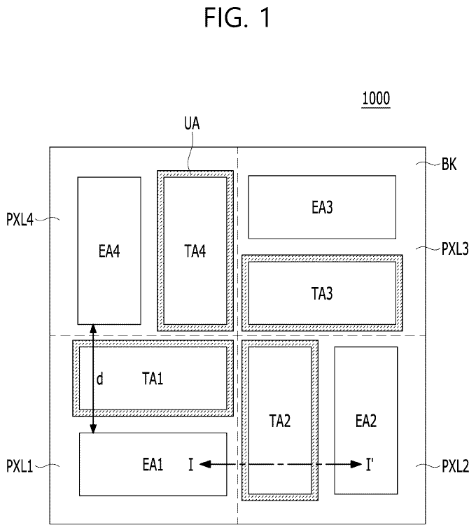

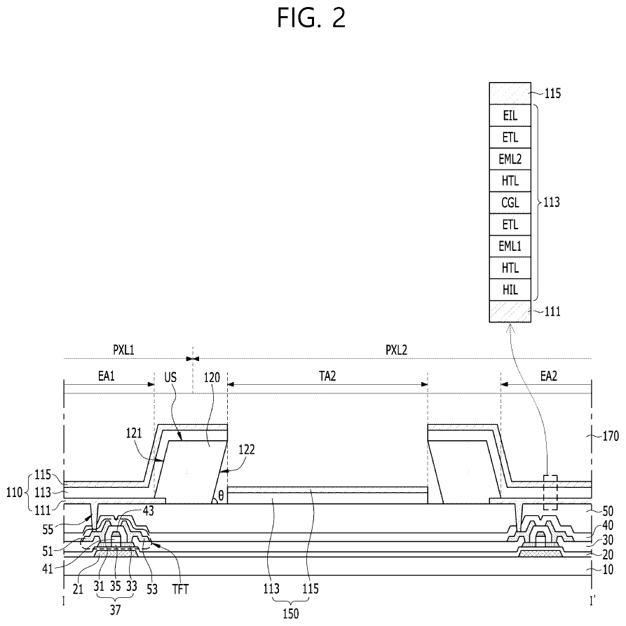

FIG. 1 is a plan view of a light-emitting display device 1000 according to a first embodiment of the present disclosure. FIG. 2 is a cross-sectional view taken along line I-I′ of FIG. 1.

Referring to FIG. 1, the light-emitting display device 1000 according to an embodiment of the present disclosure includes a plurality of sub-pixels (PXL: PXL1, PXL2, PXL3, and PXL4) including a plurality of light-emitting portions (EA: EA1, EA2, EA3, and EA4) and a plurality of light-transmitting portions (TA: TA1, TA2, TA3, and TA4), a bank structure BK exposing the light-emitting portion EA and the light-transmitting portion TA, and an undercut area UA around the light-transmitting portion TA. The undercut area UA may be provided in the bank structure BK.

The sub-pixels PXL may be defined by gate lines and data lines that are formed in a matrix form while intersecting each other on a substrate within the display area. At least one unit pixel of the sub-pixels PXL may include first to fourth sub-pixels PXL1, PXL2, PXL3, and PXL4. The first to fourth sub-pixels PXL1, PXL2, PXL3, and PXL4 may be arranged in a structure of two rows and two columns. The fourth sub-pixel PXL4 may be arranged at the intersection of the first row and the first column, the third sub-pixel PXL3 may be arranged at the intersection of the first row and the second column, the first sub-pixel PXL1 may be arranged at the intersection of the second row and the first column, and the second sub-pixel PXL2 may be arranged at the intersection of the second row and the second column.

Each of the first to fourth sub-pixels PXL1, PXL2, PXL3, and PXL4 may include one light-emitting portion EA and one light-transmitting portion. Specifically, the first sub-pixel PXL1 may include a first light-emitting portion EA1 and a first light-transmitting portion TA1, the second sub-pixel PXL2 may include a second light-emitting portion EA2 and a second light-transmitting portion TA2, the third sub-pixel PXL3 may include a third light-emitting portion EA3 and a third light-transmitting portion TA3, and the fourth sub-pixel PXL4 may include a fourth light-emitting portion EA4 and a fourth light-transmitting portion TA4. Here, the first to fourth light-emitting portions EA1, EA2, EA3, and EA4 may emit red, green, blue, and white light, respectively. For example, the light-emitting portion EA1 may emit red light, the second light-emitting portion EA2 may emit green light, the third light-emitting portion EA3 may emit blue light, the fourth light-emitting portion EA4 may emit white light. In some cases, the fourth sub-pixel PXL4 that emits white light may be omitted, and the fourth sub-pixel PXL4 may include sub-pixels that emit at least two of red light, green light, blue light, yellow light, magenta light, and cyan light. In addition, a specific type of color filter may or may not be formed in the sub-pixels PXL, and the sub-pixels PXL may emit light of their own color.

In the sub-pixels PXL according to the first embodiment, the light-emitting portion EA and the light-transmitting portion TA may be present at an area ratio of 1:1. In addition, the respective light-emitting portions EA of sub-pixels PXL may be formed to extend longitudinally in one direction, and the corresponding light-transmitting portion TA may have the same shape as the light-emitting portion EA. For example, the first light-emitting portion EA1 and the first light-transmitting portion TA1 having the same shape as each other may be arranged parallel to each other on one plane. Likewise, the second light-emitting portion EA2 and the second light-transmitting portion TA2 may be arranged parallel to each other on one plane, the third light-emitting portion EA3 and the third light-transmitting portion TA3 may be arranged parallel to each other on one plane, and the fourth light-emitting portion EA4 and the fourth light-transmitting portion TA4 may be arranged parallel to each other on one plane.

The first to fourth sub-pixels PXL1, PXL2, PXL3, and PXL4 may be arranged such that the first to fourth light-transmitting portions TA1, TA2, TA3, and TA4 are concentrated at the center in the unit pixel. Specifically, as shown in FIG. 1, the first and second light-transmitting portions TA1 and TA2 may be adjacent to each other and may be arranged vertically, and the third and fourth light-transmitting portions TA3 and TA4 are adjacent to each other and may be arranged vertically. In addition, the first and second light-transmitting portions TA1 and TA2 may be adjacent to the third and fourth light-transmitting portions TA3 and TA4. In addition, the first sub-pixel PXL1 has a shape corresponding to the fourth sub-pixel PXL4 rotated 90° counterclockwise, the second sub-pixel PXL2 has a shape corresponding to the first sub-pixel PXL1 rotated 90° counterclockwise, the third sub-pixel PXL3 has a shape a shape corresponding to the second sub-pixel PXL2 rotated 90° counterclockwise, and the fourth sub-pixel PXL4 has a shape corresponding to the third sub-pixel PXL3 rotated 90° counterclockwise.

The arrangement of the first to fourth sub-pixels PXL1, PXL2, PXL3, and PXL4 enables the first to fourth light-emitting portions EA1, EA2, EA3, and EA4 to be spaced apart from each other such that the first to fourth light-transmitting portions TA1, TA2, TA3, and TA4 are interposed therebetween. Accordingly, the light-emitting display device of the present disclosure can secure the spacing distance d between the light-emitting portions EA, thereby increasing the path of leakage current between adjacent sub-pixels PXL. In addition, the increased leakage current path can prevent leakage current between adjacent sub-pixels PXL from flowing.

In addition, the light-emitting display device 1000 of the present disclosure includes an undercut area UA around the light-transmitting portion TA in the bank structure BK that exposes the light-emitting portion EA and the light-transmitting portion TA, thereby blocking the path through which leakage current flows between sub-pixels PXL. The intermediate layer (113 in FIG. 2) on the bank structure BK may contain a material to increase charge mobility. When the intermediate layer 113 is commonly formed in a plurality of sub-pixels PXL, it may cause leakage current between adjacent sub-pixels PXL. However, in the light-emitting display device 1000 of the present disclosure, the intermediate layer 113 may be disconnected due to the undercut area UA of the bank structure BK. Accordingly, the light-emitting display device of the present disclosure can prevent leakage current from flowing between adjacent sub-pixels PXL due to the disconnected intermediate layer 113.

Specifically, referring to FIG. 2, the light-emitting display device 1000 of the present disclosure according to the first embodiment includes a plurality of thin film transistors TFTs on a substrate 10, a first electrode 111 connected to each of the thin film transistors TFTs, a light-emitting element 110 including the first electrode 111, an intermediate layer 113, and a second electrode 115, a first bank 120 exposing the light-emitting portion EA and the light-transmitting portion TA, and an encapsulation film 170 covering the light-emitting element 110. The term ‘bank’ and ‘bank structure’ is interchangeably used herein. For example, a first bank 120 may also be referred to as a first bank structure 120.

The substrate 10 is divided into a display area where the screen appears and a peripheral area where the screen does not appear, and the display area may include a plurality of sub-pixels PXL. Each sub-pixel PXL may include a light-emitting portion EA where light is actually emitted, and a non-light-emitting area where light is not emitted around the light-emitting portion EA. The non-light-emitting portion may include a light-transmitting portion TA through which external light is transmitted. Here, the areas of the light-emitting portion EA and the light-transmitting portion TA are divided based on the bank structure BK or the first bank 120, but the light-emitting portion EA is not limited thereto. Depending on the light-emitting form, the light-emitting portion EA may be defined as an area extending from the first side surface 121 of the first bank 120 to a part of the top of the first bank 120 and the light-transmitting portion TA may be defined as an area extending from the second side surface 122 of the first bank 120 to a part of the top of the first bank 120. For example, when the substrate 10 is a plastic substrate, it may contain polyimide or polyamide. The first bank 120 also has an upper surface US between the first side surface 121 and the second side surface 122.

On the substrate 10, various signal wires such as data signal wires and gate signal wires, transistors such as switching thin film transistors and driving thin film transistors, and circuit elements including capacitors may be formed for each sub-pixel PXL. Transistors such as switching thin film transistors and driving thin film transistors may not overlap with the light-transmitting portions TA. For convenience of explanation, a single thin film transistor TFT driving one light-emitting portion EA may be provided. In addition, as shown in FIG. 2, the thin film transistor TFT may overlap the light-emitting portion EA, but the present disclosure is not limited thereto and does not overlap with the light-emitting portion EA and overlaps the first bank 120 of the non-light-emitting portion.

A thin film transistor TFT includes an active layer 37, a gate electrode 43 overlapping the channel region 35 of the active layer 37 with a gate insulating film 41 therebetween, and a source electrode 53 and a drain electrode 51 connected to both sides of the active layer 37.

The active layer 37 of the thin film transistor TFT includes a source region 33 and a drain region 31 on both sides thereof with a channel region 35 therebetween. Each of the source region 33 and the drain region 31 is formed of a semiconductor material doped with n-type or p-type impurities. The channel region 35 overlapping the gate electrode 43 may be formed of a semiconductor material not doped with n-type or p-type impurities.

The gate electrode 45 of the thin film transistor TFT is provided to overlap the channel region 35 of the active layer 37, while having the same width as the channel region 35, with the gate insulating film 41 interposed therebetween. The gate insulating film 41 overlaps the channel region 25 of the active layer 27 in the same pattern as the gate electrode 43. For example, the gate electrode 43 may be a single layer or multiple layers containing one of molybdenum (Mo), aluminum (Al), chromium (Cr), gold (Au), titanium (Ti), nickel (Ni), neodymium (Nd), and copper (Cu), or an alloy thereof. Meanwhile, the gate insulating film 41 may contain an inorganic insulating material, and may include, for example, a silicon oxide film (SiOx), a silicon nitride film (SiNx), a silicon oxynitride film (SiOxNy), or multiple films thereof.

Meanwhile, the light-blocking layer 21 on the substrate 10 overlaps at least the channel region 35 of the active layer 37 of the thin film transistor TFT and is disposed below the active layer 37. The light-blocking layer 21 prevents external light from penetrating the substrate 10 and being transmitted to the thin film transistor TFT. For example, the light-blocking layer 21 may be a single layer containing a metal material such as molybdenum (Mo), titanium (Ti), aluminum-neodymium (AlNd), aluminum (Al), chromium (Cr), or an alloy thereof, or a multilayer structure using the same.

As illustrated in FIG. 2, the thin film transistor TFT is electrically connected to the light-emitting element 110. Further, the thin film transistor TFT overlaps the light-emitting element 110 from a plan view.

The buffer film 20 on the light-blocking layer 21 is provided to cover the light-blocking layer 21. For example, the buffer film 20 may have a single-layer or multilayer structure containing silicon oxide (SiOx) or silicon nitride (SiNx).

The interlayer insulating film 30 on the buffer film 20 includes a source contact hole and a drain contact hole exposing each of the source region 33 and the drain region 31 of the active layer 37, and covers the gate insulating film 41 and the gate electrode 43. For example, the interlayer insulating film 30 may contain an inorganic insulating material. For example, the interlayer insulating film 30 may be a single layer or multiple layers containing a silicon oxide film (SiOx), a silicon nitride film (SiNx), or a silicon oxynitride film (SiOxNy).

The source electrode 53 and the drain electrode 51 may be provided in the same layer on the interlayer insulating film 30. Each of the source electrode 53 and the drain electrode 51 is connected to the source region 33 and drain region 31 of the active layer 37 through a source contact hole and a drain contact hole. For example, the source electrode 53 and the drain electrode 51 may be a single layer containing a metal material such as molybdenum (Mo), aluminum (Al), chromium (Cr), gold (Au), titanium (Ti), nickel (Ni), neodymium (Nd), copper (Cu), or an alloy thereof, or a multiple-layer structure using the same.

The passivation layer 40 on the interlayer insulating film 30 may be provided to cover the thin film transistor region TFT. As a result, the thin film transistor area TFT can be protected by the passivation layer 40. For example, the passivation layer 40 is a type of inorganic insulating film and may be provided as a single layer or multiple layers of a silicon oxide film (SiOx), a silicon nitride film (SiNx), or a silicon oxynitride film (SiOxNx).

A planarization layer 50 may be provided on the passivation layer 40. The planarization layer 50 is formed to a thickness sufficient to planarize the surface step at the top of the thin film transistor region TFT and may be formed of an organic insulating film. In some cases, when the planarization layer 50 also functions to protect the thin film transistor TFT, the passivation layer 40 may be omitted. For example, the planarization layer 50 is a type of organic insulating film and may be any one of photoacryl, polyimide, benzocyclobutene resin, and acrylate. In some cases, the planarization layer 50 may be formed in multiple layers.

A light-emitting element 110 including a stack structure of a first electrode 111, an intermediate layer 113, and a second electrode 115 may be provided on the planarization layer 50. In addition, the first bank 120 may be provided over the entire area where the light-emitting portion EA and the light-transmitting portion TA are not present between the planarization layer 50 and the light-emitting element 110. The light-emitting element 110 may be operated based on the mechanism in which, when current is supplied from the power voltage line to the second electrode 115 and a high-voltage current is supplied from the thin film transistor TFT to the first electrode 111, an electric field is formed between the first electrode 111 and the second electrodes 115, and the intermediate layer 113 emits light.

The first electrode 111 may be provided in each of the plurality of sub-pixels PXL and may not overlap the light-transmitting portion TA. The first electrode 111 may be formed in a multilayer structure including a transparent conductive film and an opaque conductive film with high reflection efficiency. The transparent conductive film of the first electrode 111 contains a material with a relatively high work function value such as indium tin oxide (ITO) or indium zinc oxide (IZO), and the opaque conductive film may be a single layer or multiple layers containing any one or an alloy thereof selected from the group consisting of silver (Ag), aluminum (Al), copper (Cu), molybdenum (Mo), titanium (Ti), nickel (Ni), chromium (Cr), or tungsten (W). For example, the first electrode 111 may have a structure in which a transparent conductive film, an opaque conductive film, and a transparent conductive film are sequentially stacked, or a structure in which a transparent conductive film and an opaque conductive film are sequentially stacked.

The first bank 120 covering the edge of the first electrode 111 may be provided over the entire surface of the planarization layer 50 such that the light-emitting portions EA1 and EA2 and the light-transmitting portion TA2 are exposed. The first bank 120 exposing the light-emitting portions EA1 and EA2 has a first side surface 121 having a positive taper shape, and the first bank 120 exposing the light-transmitting portion TA2 has a second side surface 122 having a negative taper shape.

In some embodiments, the intermediate layer 113 of the light-emitting element 110 is on the upper surface US of the first bank 120. Further, the second electrode 115 of the light-emitting element 110 is on the upper surface US of the first bank 120.

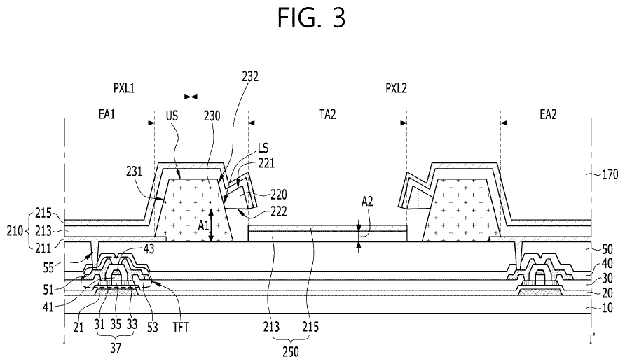

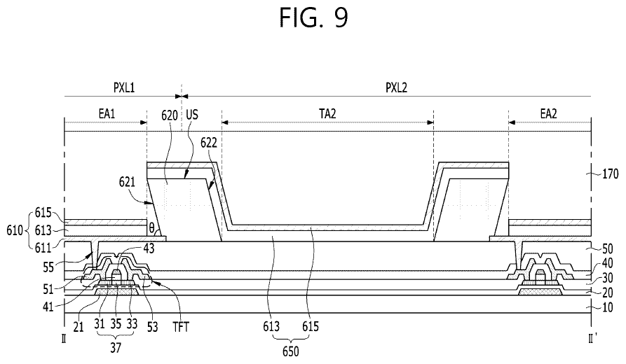

In FIG. 2, the first side surface 121 and the second side surface 122 are inclined in the same direction. The first side surface 121 can have a first inclination angle with respect to the planarization layer 50 and the second side surface 122 can have a second inclination angle θ (also referred to as a second side angle θ) with respect to the planarization layer 50. In some embodiments, the first inclination angle of the first side surface 121 may be the same as the second inclination angle θ of the second side surface 122. In other embodiments, while the first inclination angle of the first side surface 121 may not be the same as the second inclination angle θ of the second side surface 122, the first side surface 121 and the second side surface 122 may generally extend in the same direction (see FIGS. 2 and 9). However, in a completely different embodiment, the first side surface 121 may extend in a first direction and the second side surface 122 may extend in a second direction transverse to the first direction (see FIGS. 3, 4, 5, 6, and 7).

Referring to FIG. 2, according to some embodiments, either the intermediate layer 113 or the second electrode 115 continuously and contiguously extends from the light-emitting element 110 to the upper surface US of the first bank 120. In some embodiments, either the intermediate layer 113 or the second electrode 115 covers the first side surface 121 of the first bank 120. Here, the intermediate layer 113 directly contacts both the first side surface 121 and the upper surface US of the first bank 120. However, the intermediate layer 113 is spaced apart from the second side surface 122 of the first bank 120 and does not directly contact the second side surface 122 of the first bank 120.

In the present disclosure, the negative taper shape means that a side surface of an object is negatively inclined with respect to a forming plane. The negative taper can be used as the same meaning with “a reverse taper”.

In the present disclosure, the positive taper shape means that a side surface of an object is positively inclined with respect to a forming plane. The positive taper can be used as the same meaning with “a regular taper”.

The intermediate layer 113 may be formed more uniformly on the first side surface 121 of the first bank 120 having a positive taper shape than on the second side surface 122 having a negative taper shape. The intermediate layer 113 on the first bank 120 may be deposited so as to be concentrated below the side surface of the negative taper shape. As such, when the side surface of the negative taper shape is provided in the area adjacent to the light-emitting portion, during generation of an electric field in the light-emitting device, the electric field generated in the area where the intermediate layer material is concentrated under the negative taper is not emitted as light and causes deterioration of the light-emitting device. This may cause the problem of shortening the lifespan of the light-emitting device. However, the first bank 120 according to this embodiment has a negative taper shape on the second side surface 122 adjacent to the light-transmitting portion TA2, and the first side surface 121 has a positive taper shape, thereby preventing the phenomenon in which the deposition material is concentrated at the corner between the first side surface 121 and the first electrode 111. Accordingly, in the light-emitting display device of the present disclosure, an electric field can be constantly applied to the light-emitting portions EA1 and EA2, thereby preventing deterioration of the light-emitting element 110.

The second side surface 122 of the first bank 120 may have a negative taper shape. The second side surface 122 having the negative taper shape may have a predetermined angle through a process such as over-etching. Here, the area where the second side surface 122 of the first bank 120 is formed may be an undercut area (UA in FIG. 1). The outer angle θ with respect to the second side surface 122 may be at least less than 90°. More specifically, the second side angle θ may be set to 70° or less so that the layer deposited on the top of the first bank 120 is disconnected, but the present disclosure is not limited thereto. Depending on characteristics such as the thickness of the first bank 120 or the thickness and step coverage of the intermediate layer 113 deposited on the first bank 120, the second side angle θ may be about 70°. Therefore, the second side surface 122 of the first bank 120 has a negative taper shape, so that the intermediate layer 133 deposited on the first bank 120 can be separated between the light-emitting portions EA1 and EA2 and the light-transmitting portion TA2. Accordingly, the light-emitting display device of the present disclosure has a second side surface 122 having a negative taper shape, adjacent to the light-transmitting portion TA2, thereby preventing deterioration of the light-emitting element 110 and at the same time, preventing leakage current from flowing between adjacent sub-pixels PXL1 and PXL2.

For example, the first bank 120 may be made of an organic material such as a polyimide, acrylate, or benzocyclobutene resin.

The intermediate layer 113 may be provided over the entire area of the substrate 10 on the first electrode 111 and the first bank 120. The intermediate layer 113 may refer to a single stack organic layer including multiple layers including a hole injection layer (HIL), a hole transport layer (HTL), a light-emitting layer (EML1 or EML2), an electron transport layer (ETL), and an electron injection layer (EIL). However, as shown in FIG. 2, the intermediate layer 113 has a light-emitting unit with a tandem structure including a plurality of stacks (first stack and second stack), each having first and second light-emitting layers (EML1 and EML2), and a charge generation layer (CGL) between the stacks. The tandem structure is not limited to the two-stack structure shown and may include multiple stacks of three or more stacks.

Here, the first and second light-emitting layers (EML1, EML2) in the plurality of stacks may be light-emitting layers of the same color that emits one of red, green, and blue light, and are partially provided in each of the sub-pixels PXL. Multiple layers of the intermediate layer 113 excluding the first and second light-emitting layers (EML1 and EML2) may be provided as a common mask over the entire surface of the substrate 10. Alternatively, when white light is emitted by the first and second light-emitting layers (EML1 and EML2) in a two-stack structure or through the light-emitting layers in a multiple stack structure of three or more stacks, each of the light-emitting layers may be provided over the entire surface of the substrate 10, like the other intermediate layers 113.

The charge generation layer (CGL) may be made of an n- and p-type double layer. The n-type charge generation layer and the p-type charge generation layer of the charge generation layer (CGL) may include an n-type dopant and a p-type dopant, respectively. For example, the n-type dopant may include a metal dopant such as lithium (Li) or ytterbium (Yb). This metal dopant increases charge mobility, so that the n-type charge generation layer formed commonly in a plurality of sub-pixels may cause leakage current between adjacent sub-pixels. In addition to the n-type charge generation layer, layers of the intermediate layer 113 containing materials with high charge mobility may cause leakage current.

However, the intermediate layer 113 of the present disclosure may be discontinuously deposited on the light-transmitting portion TA2 at the top of the first bank 120, rather than being continuously deposited on the adjacent light-transmitting portion TA2 due to the second side surface 122 of the first bank 120. The intermediate layer 113 on the light-transmitting portion TA2 may be provided as a dummy pattern 150 on the light-transmitting portion TA2 that is disconnected from the intermediate layer 113 on the first bank 120. Accordingly, in the light-emitting display device according to the present disclosure, the intermediate layer 113 may be uniformly deposited in the light-emitting portions EA1 and EA2 and may be disconnected near the light-transmitting portion TA2, thereby preventing deterioration of the light-emitting element 110 and simultaneously preventing leakage current from flowing between the sub-pixels PXL through the intermediate layer 113.

The second electrode 115 on the intermediate layer 113 may be formed over the entire surface of the substrate 10 through a common mask. The second electrode 115 made of a metal is not limited to the configuration shown in FIG. 2 and has better step coverage characteristics compared to the intermediate layer 113 made of an organic material, or both organic and inorganic materials, such that it covers the exposed side surface of the intermediate layer 113 on the bank 120. In addition, the second electrode 115 may be separated on the light-transmitting portion TA2 by at least the second side surface 122 of the bank 120 having a negative taper shape. Accordingly, the dummy pattern 150 on the light-transmitting portion TA2 may include the second electrode 115 as well as the intermediate layer 113. For example, the second electrode 115 may be made of a transparent conductive material such as indium tin oxide (ITO) or indium zinc oxide (IZO), and may be made of silver (Ag), aluminum (Al), magnesium (Mg) or calcium (Ca) having a thickness small enough to transmit light, or an alloy thereof.

The encapsulation film 170 may be provided on the second electrode 115 to completely cover the display area and the non-display area. The encapsulation film 170 prevents oxygen and moisture from penetrating into the light-emitting element 110, thereby improving the lifespan of the light-emitting display device. For example, the encapsulation film 170 may be formed by stacking one or more pairs of an inorganic encapsulation film and an organic encapsulation film, or may be formed by stacking a filler material and a counter substrate.

As shown in FIG., the dummy pattern 150 is adjacent to the first bank 120. The dummy pattern 150 includes the intermediate layer 113 and the second electrode 150. The intermediate layer 113 and the second electrode 150 of the dummy pattern 150 are the intermediate layer 113 and the second electrode 150 from the light-emitting element 110. Namely, the intermediate layer 113 and the second electrode 150 of the dummy pattern 150 were deposited at the same time using the same material when the intermediate layer 113 and the second electrode 150 of the light-emitting element 110 were deposited. However, as shown, the intermediate layer 113 and the second electrode 150 of the dummy pattern 150 are disconnected from the intermediate layer 113 and the second electrode 150 that is disposed on the upper surface US of the first bank 120.

FIG. 3 is a cross-sectional view taken along line I-I′ of FIG. 1 according to the second embodiment. Hereinafter, description of the same configuration as the previous embodiment will be omitted.

Referring to FIG. 3, the light-emitting display device according to the second embodiment of the present disclosure includes a plurality of thin film transistors TFTs on a substrate 10, a first electrode 211 connected to each of the plurality of thin film transistors TFTs, a light-emitting element 210 including a first electrode 211, an intermediate layer 213, and a second electrode 215, a bank structure (BK in FIG. 1) exposing the light-emitting portions EA1 and EA2 and the light-transmitting portion TA2, and an encapsulation film 170 covering the light-emitting element 210.

The intermediate layer 213 and the second electrode 215 on the light-transmitting portion TA2 may be provided as a dummy pattern 250. The intermediate layer 213 of the dummy pattern 250 on the light-transmitting portion TA2 is disconnected from the intermediate layer 213 on the bank structure BK. The second electrode 215 of the dummy pattern 250 on the light-transmitting portion TA2 is disconnected from the second electrode 215 on the bank structure BK.

In the light-emitting display device according to the second embodiment of the present disclosure, the bank structure BK further includes a first bank 220 and a second bank 230 below the first bank 220. In addition, in the light-emitting display device according to the second embodiment of the present disclosure, the lower surface of the first bank 220 may contact the side surface of the second bank 230 adjacent to the light-transmitting portion TA2. For example, the first bank 220 and the second bank 230 may contain the same material, but the present disclosure is not limited thereto. In some cases, the first bank 220 and the second bank 230 may contain different materials.

The second bank 230 includes a first side surface 231, a second side surface 232 opposite the first side surface 231, and an upper surface US between the first side surface 231 and the second side surface 232. The first bank 220 includes a first side surface 221, a second side surface 222 opposite the first side surface 221, and a lower surface LS between the first side surface 221 and the second side surface 222. The lower surface LS of the bank 220 directly contacts the second side surface 232 of the second bank 230. The dummy pattern 250 may be disconnected from the second side surface 232 of the second bank 230 and the first bank 220.

The first bank 220 may have a first side surface 221 adjacent to the light-emitting portions EA1 and EA2 and a second side surface 222 adjacent to the light-transmitting portion TA2. Here, the second side surface 222 of the first bank 220 may be a surface facing the substrate 10 and may have a negative taper shape. Meanwhile, the lower surface of the first bank 220 may be defined as a surface contacting the second bank 230 between the first side surface 221 and the second side surface 222. As the lower surface of the first bank 220 contacts the side surface 231 of the second bank 230, the lower surface and upper surface of the first bank 220 are parallel to the side surface 231 of the second bank 230. In other words, the intermediate layer 213 may be easily deposited on the upper surface of the first bank 220. However, while the second side surface 222 of the first bank 220 has a negative taper shape, the first bank 220 may form an undercut on the side surface 231 of the second bank 230. Accordingly, the first bank 220 has a second side surface 222 having a negative taper shape, thereby disconnecting the intermediate layer 213. The area occupied by the first bank 220 between the light-emitting portion EA and the light-transmitting portion TA2 may correspond to the undercut area UA in FIG. 1.

In addition, the first bank 220 may be disposed on the side surface 231 of the second bank 230 at a height that is at least higher than the thickness of the intermediate layer 213. That is, the vertical distance A1 between the lower surface of the second bank 230 and the first bank 220 may be greater than the thickness A2 of the intermediate layer 213. More specifically, the distance A1 may be a vertical distance between the edge between the lower surface and the second side surface 222 of the first bank 220, and the lower surface of the second bank 230. Accordingly, the sufficient spacing distance between the second side surface 222 of the first bank 220 and the planarization layer 50, which is at least the thickness A2 of the intermediate layer 213, enables the intermediate layer 213 to be separated by the first bank 220.

As such, the second side surface 222 of the first bank 220 has a negative tapered structure and is spaced by a predetermined distance A1 from the lower surface of the second bank 230 on the side surface 231 of the second bank 230, to disconnect the intermediate layer 213 deposited on the first bank 220. Accordingly, the material of the intermediate layer 213, which is deposited as a common mask over the entire surface of the substrate 10, is separated into the light-transmitting portion TA2 from the light-emitting portions EA1 and EA2 by the second side surface 222 having a negative taper shape of the first bank 220.

Meanwhile, the first side surface 221 adjacent to the light-emitting portions EA1 and EA2 of the first bank 220 may have various shapes depending on the process method for forming the second side surface 222 with a negative taper shape. FIG. 3 shows that the first side surface 221 adjacent to the light-emitting portions EA1 and EA2 of the first bank 220 has a negative taper shape. The first side surface 221 having the negative taper shape may have an inclination with respect to the deposition direction of the material of the intermediate layer 213. Accordingly, less of the intermediate layer 213 may be deposited on the first side surface 221 of the negative taper shape compared to the side perpendicular to the direction of deposition of the material of the intermediate layer 213. Accordingly, because the first side surface 221 has a negative taper shape, the intermediate layer 213 may be disconnected relatively easily, but the present disclosure is not limited thereto and the first side surface 221 of the first bank 220 may have a positive taper shape or be perpendicular to the side surface 231 of the second bank 230.

The side surface 231 of the second bank 230 may have a positive taper shape. The side surface 231 of the second bank 230 adjacent to the light-emitting portions EA1 and EA2 has a positive taper shape and the intermediate layer 213 deposited on the first electrode 211 and the second bank 230 may be deposited uniformly. Accordingly, the light-emitting display device of the present disclosure enables uniform deposition of the intermediate layer 213 material in the light-emitting portions EA1 and EA2, thereby preventing deterioration of the light-emitting element 210.

The width between the light-emitting portions EA1 and EA2 and the light-transmitting portion TA2 on the cross-sectional surface of the first bank 220 and the second bank 230 according to the second embodiment may be equal to the width between the light-emitting portions EA1 and EA2, and the light-transmitting portion TA2 on the cross section of the first bank 120 according to the first embodiment. For this purpose, the first bank 220 according to the second embodiment may have a smaller size than that of the first bank 120 according to the first embodiment. Accordingly, even if one additional bank is provided in the width direction in the second embodiment, the size of the first bank 220 according to the second embodiment is different from that of the first embodiment, so that the area between the light-emitting portions EA1 and EA2 and the light-transmitting portion TA2 may not be separately occupied, but the present disclosure is not limited thereto. In some cases, the cross-sectional width occupied by the bank structure BK according to the first embodiment and the cross-sectional width occupied by the bank structure BK according to the second embodiment may be different without adjusting the size of the first bank 220.

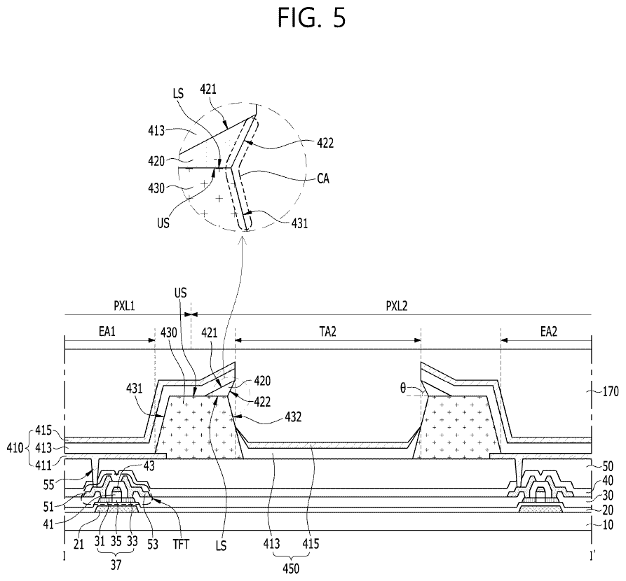

According to some embodiments, the lower surface LS of the bank 220 directly contacts either the upper surface US of a bank structure or the second side surface 232 of a bank structure (e.g., a bank 230; see FIG. 3). FIG. 5 illustrates an example where the lower surface LS of the bank 420 directly contacts the upper surface US of the bank 430.

In some embodiments, either the intermediate layer 213, 313, 413, 513, 713, or the second electrode 215, 315, 415, 515, 715 continuously and contiguously extends from the light-emitting element 210, 310, 410, 510, 710 to the upper surface US of the bank 230, 330, 430, 530, 730 and the first side surface 231, 331, 431, 731 of the bank.

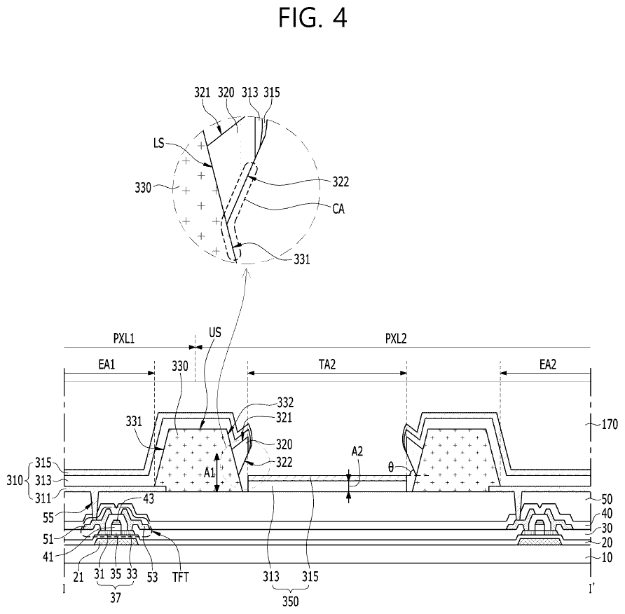

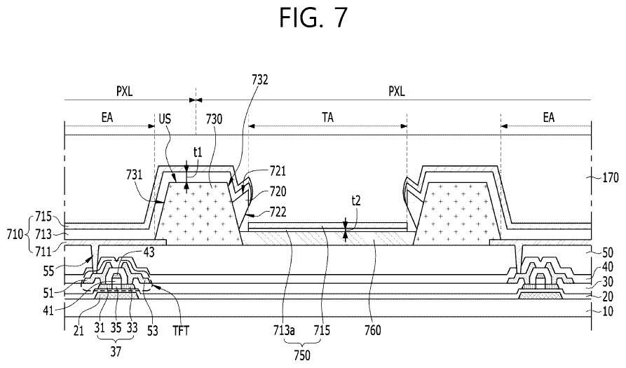

In some embodiments, either the intermediate layer or the second electrode is not in contact with the second side surface 222 of the bank 220 (in FIG. 3). In some embodiments, either the intermediate layer or the second electrode is not in contact with the second side surface 322 of the bank 320 (in FIG. 4). In some embodiments, either the intermediate layer or the second electrode is not in contact with the second side surface 422 of the bank 420 (in FIG. 5). In some embodiments, either the intermediate layer or the second electrode is not in contact with the second side surface 722 of the bank 720 (in FIG. 7).

FIG. 4 is a cross-sectional view taken along line I-I′ of FIG. 1 according to a third embodiment of the present disclosure.

Referring to FIG. 4, the light-emitting display device according to the third embodiment includes a plurality of thin film transistors TFTs on a substrate 10, a first electrode 311 connected to each of the plurality of thin film transistors TFTs, a light-emitting element 310 including a first electrode 311, an intermediate layer 313, and a second electrode 315, a bank structure (BK in FIG. 1) exposing the light-emitting portions (EA1, and EA2) and the light-transmitting portion TA2, and an encapsulation film 170 covering the light-emitting element 310. In the bank structure BK, a second bank 330 includes a first side surface 331, a second side surface 332 opposite the first side surface 331, and an upper surface US between the first side surface 331 and the second side surface 332. A first bank 320 includes a first side surface 321, a second side surface 322 opposite the first side surface 321, and a lower surface LS between the first side surface 321 and the second side surface 322. The lower surface LS of the first bank 320 directly contacts the second side surface 332 of the second bank 330.

The intermediate layer 313 and the second electrode 315 on the light-transmitting portion TA2 may be provided as a dummy pattern 350. The intermediate layer 313 of the dummy pattern 350 on the light-transmitting portion TA2 is disconnected from the intermediate layer 313 on the bank structure BK. The second electrode 315 of the dummy pattern 350 on the light-transmitting portion TA2 is disconnected from the second electrode 315 on the bank structure BK. The dummy pattern 350 may be disconnected from the second side surface 332 of the second bank 330 and the first bank 320.

In the light-emitting display device of the present disclosure according to the third embodiment, the bank structure BK may have a recess (CA) on a side adjacent to the light-transmitting portion TA2. Specifically, the bank structure BK further includes a first bank 320 and a second bank 330 below the first bank 320. In addition, in the light-emitting display device according to the third embodiment of the present disclosure, the lower surface of the first bank 320 may contact the side surface adjacent to the light-transmitting portion TA2 of the second bank 330. Here, the recess CA may be provided between the second side surface 322 of the first bank 320 and the side surface 331 of the second bank 330. This recess CA may cause an undercut in the bank structure BK.

For this purpose, the second side surface 322 of the first bank 320 facing the substrate 10 may have a positive taper shape with respect to the second bank 330. In addition, the second side surface 322 may have an outer angle θ of 70° or less with respect to the substrate 10. Accordingly, the intermediate layer 313 deposited in the direction of the substrate 10 may be disconnected by the second side surface 322 of the first bank 320 having a positive taper shape. In addition, since the first bank 320 is located on the side surface 331 of the second bank 330 adjacent to the light-transmitting portion TA2, the intermediate layer 313 may be disconnected near the light-transmitting portion TA2. That is, the material for the intermediate layer 313 may be separated from the light-emitting portions EA1 and EA2 into the light-transmitting portion TA2 by the first bank 320.

In addition, the upper surface between the first side surface 321 and the second side surface 322 of the first bank 320 may be located at least at a greater height than the thickness A2 of the intermediate layer 313 on the side surface 331 of the second bank 330. That is, the vertical distance A1 of the first bank 320 from the lower surface of the second bank 330 may be greater than the thickness A2 of the intermediate layer 313. Accordingly, the sufficient spacing distance between the second side surface 322 of the first bank 320 and the planarization layer 50, which is at least not less than the thickness A2 of the intermediate layer 313, enables the intermediate layer 313 to be separated into the light-transmitting portion TA2 by the first bank 320.

Meanwhile, FIG. 4 shows that the first side surface 321 adjacent to the light-emitting portions EA1 and EA2 of the first bank 320 is reversely tapered or negatively inclined to the side surface 331 of second bank 330 adjacent to light-transmitting portion TA2, but the first side surface 321 of the first bank 320 is not limited thereto and may be reversely tapered or negatively inclined to the side surface 331 of the second bank 330, regularly tapered or positively inclined to the side surface 331 of the second bank 330, or be perpendicular to the side surface 331 of the second bank 330.

FIG. 5 is a cross-sectional view taken along line I-I′ of FIG. 1 according to a fourth embodiment of the present disclosure.

Referring to FIG. 5, the light-emitting display device according to the fourth embodiment includes a plurality of thin film transistors TFTs on a substrate 10, a first electrode 411 connected to each of the plurality of thin film transistors TFTs, a light-emitting element 410 including a first electrode 411, an intermediate layer 413, and a second electrode 415, a bank structure (BK in FIG. 1) exposing the light-emitting portions (EA1, EA2) and the light-transmitting portion TA2, and an encapsulation film 170 covering the light-emitting element 410. In the bank structure, a second bank 430 includes a first side surface 431, a second side surface 432 opposite the first side surface 431, and an upper surface US between the first side surface 431 and the second side surface 432. A first bank 420 includes a first side surface 421, a second side surface 422 opposite the first side surface 421, and a lower surface LS between the first side surface 421 and the second side surface 422. The lower surface LS of the first bank 420 directly contacts the upper surface US of the second bank 430.

The intermediate layer 413 and the second electrode 415 on the light-transmitting portion TA2 may be provided as a dummy pattern 450. The intermediate layer 413 of the dummy pattern 450 on the light-transmitting portion TA2 is disconnected from the intermediate layer 413 on the bank structure BK. The second electrode 415 of the dummy pattern 450 on the light-transmitting portion TA2 is disconnected from the second electrode 415 on the bank structure BK. The dummy pattern 450 may be disconnected from and the first bank 420.

In the light-emitting display device according to the fourth embodiment of the present disclosure, the bank structure BK may have an undercut area (UA in FIG. 1) on a side adjacent to the light-transmitting portion TA2. Specifically, the bank structure BK according to the fourth embodiment may further include a first bank 420 and a second bank 430 below the first bank 420. At the same time, the lower surface LS of the first bank 420 may contact the upper surface US of the second bank 430. At this time, the second side surface 422 adjacent to the light-transmitting portion TA2 of the first bank 420 has a negative taper shape and may cause an undercut in the bank structure BK. An upper surface 421 of the first bank 420 contacts the intermediate layer 413.

As shown in FIG. 5, the lower surface LS of the first bank 420 may be provided on the upper surface US adjacent to the light-transmitting portion TA2 of the second bank 430, to provide a recess CA. In other words, the recess CA may be provided between the second side surface 422 of the first bank 420 and the side surface 432 of the second bank 430.

The second side surface 422 of the first bank 420 may have an outer angle θ of 70° or less with respect to the substrate 10. This enables the intermediate layer 413 to be disconnected by the second side surface 422 of the first bank 420. The outer angle θ of the second side surface 422 is 70°, which facilitates disconnection of the intermediate layer 413, but the present disclosure is not limited thereto. The outer angle θ of the second side surface 422 is about 70° depending on the step coverage characteristics of the material forming the intermediate layer 413 or the thickness of the intermediate layer 413.

Accordingly, the first bank 430 has a second side surface 422 having a negative taper shape, thus causing the intermediate layer 413 deposited on the first bank 420 to be disconnected in the area adjacent to the light-transmitting portion TA2. Therefore, the intermediate layer 413, which is deposited as a common mask on the entire surface of the substrate 10, is separated from the light-emitting portions EA1 and EA2 into the light-transmitting portion TA2 by the second side surface 422 having a negative taper shape of the first bank 420.

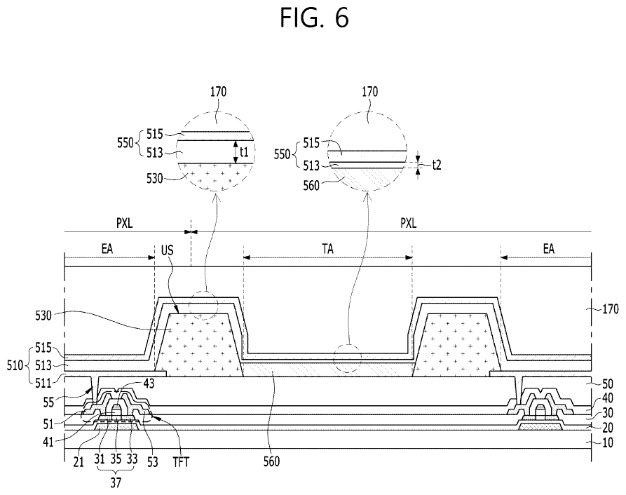

FIG. 6 is a light-emitting display device according to a fifth embodiment of the present disclosure.

Referring to FIG. 6, the light-emitting display device according to the fifth embodiment includes a plurality of thin film transistors TFTs on a substrate 10, a first electrode 511 connected to each of the plurality of thin film transistors TFTs, a light-emitting element 510 including a first electrode 511, an intermediate layer 513, and a second electrode 515, a bank 530 exposing the light-emitting portions (EA1, EA2) and the light-transmitting portion TA2, a nucleation inhibition layer 560 on the light-transmitting portion TA, and an encapsulation film 170 covering the light-emitting element 510.

The light-emitting display device of the present disclosure according to the fifth embodiment includes one bank 530, and the side surfaces of the bank 530 adjacent to the light-emitting portion EA and the light-transmitting portion TA may have a positive taper shape. In the structure of the bank 530 having a positive taper shape, disconnection of the intermediate layer 513 may not be easy. However, in the light-emitting display device of the present disclosure according to the fifth embodiment, in order to prevent leakage current from flowing between adjacent sub-pixels PXL through the intermediate layer 513, a nucleation inhibition layer 560 is provided in the light-transmitting portion TA.

The nucleation inhibition layer 560 may be provided on the planarization layer 50 between the banks 530 exposing light-transmitting portion TA. The nucleation inhibition layer 560 have a surface that has a low affinity for conductive materials and thus suppresses deposition of the intermediate layer 513 containing conductive materials. For this purpose, the nucleation inhibition layer 560 and the intermediate layer 513 may each include materials with the following characteristics.

The nucleation inhibition layer 560 includes an organic material. In some embodiments, the nucleation inhibition layer 560 may include an organic material and an organic polymer, and may contain a polycyclic aromatic compound containing at least one heteroatom such as N (nitrogen), S (sulfur), O (oxygen), phosphorus (P), or aluminum (A1). The polycyclic aromatic compound may include an organic molecule including a core moiety and at least one terminal moiety bonded to the core moiety. For example, the material for the nucleation inhibition layer 560 is 3-(4-biphenyl)-4-phenyl-5-tert-butylphenyl-1,2,4-triazole (TAZ), aluminum (III) bis (2-methyl-8-quinolinato)-4-phenylphenolate (BAlq), 2-(4-(9,10-di(naphthalen-2-yl)anthracen-2-yl)phenyl)-1-phenyl-1H-benzo-[D]imidazole, 8-hydroxyquinoline lithium (Liq), and N(diphenyl-4-yl)9,9-dimethyl-N-(4 (9-phenyl-9H-carbasol-3-yl)phenyl)-9H-fluoren-2-amine, or the like.

Meanwhile, the nucleation inhibition layer 560 may have a thickness sufficient for the light-transmitting portion TA to maintain a predetermined transmittance. In addition, the material for the nucleation inhibition layer 560 may be selectively limited to a material that suppresses deposition of materials of the intermediate layer 513 in order to maintain a predetermined transmittance of the light-transmitting portion TA.

The intermediate layer 513 is composed of multiple layers including a hole injection layer (HIL), a hole transport layer (HTL), a light-emitting layer (EML), an electron transport layer (ETL), an electron injection layer (EIL), and a charge generation layer (CGL) between the stacks. In addition, each layer forming the intermediate layer 513 may include a conductive material. For example, the materials for the hole injection layer (HIL) and the hole transport layer (HTL) may be low-molecular materials, high-molecular materials such as PEDPT: PSS, MoO₃, ReO₃, and NiO_{X}, and metal oxides, but are not limited thereto. The materials for the hole injection layer (HIL) and the hole transport layer (HTL) may be materials having hole injection and hole transport functions, respectively, and being generally known hole injection and hole transport materials. For example, the electron injection layer (EIL) and the electron transport layer (ETL) are alkali metals with low work functions such as Li, Ca, and Mg, metal ions such as LiF and CsF, and compounds such as Cs₂CO₃ and RbCO₃, but the electron injection layer (EIL) and the electron transport layer (ETL) are not limited thereto. Materials for the electron injection layer (EIL) and the electron transport layer (ETL) are materials that have electron injection and electron transport functions, respectively, and are generally known electron injection and electron transport materials. The charge generation layer (CGL) may have a double layer structure of n-type and p-type charge generation layers (CGL). The n-type charge generation layer and the p-type charge generation layer of the charge generation layer (CGL) may include an n-type dopant and a p-type dopant, respectively. For example, the n-type dopant may include a metal dopant such as lithium (Li) or ytterbium (Yb).

As such, the multiple layers constituting the intermediate layer 513 may include a conductive material as well as an organic material. When the layers forming the intermediate layer 513 are sequentially deposited on the surface of the nucleation inhibition layer 560, the conductive material contained in each layer may not be adhered to the surface of the nucleation inhibition layer 560 due to low affinity for the material forming the nucleation inhibition layer 560. In other words, the conductive materials for forming the intermediate layer 513 may have a very low surface adhesion probability to the nucleation inhibition layer 560. Here, the surface adhesion probability may be measured by depositing an amount of conductive material required to form a closed-pack layer having an average thickness of 1 nm on the surface of the nucleation inhibition layer 560, in the case of depositing the conductive material. Specifically, the conductive material is simultaneously deposited on the surface of the nucleation inhibition layer 560, and the average thickness of the conductive material deposited on the substrate is compared when the average thickness of the layer concentrated on the surface of the nucleation inhibition layer 560 reaches 1 nm, to obtain the probability of surface adhesion of the conductive material for the nucleation inhibition layer 560.

The deposition of the intermediate layer 513 containing a conductive material may be fixed to the surface of the nucleation inhibition layer 560 through a nucleation and growth process. However, as described above, the intermediate layer 513 containing a conductive material may have a low probability of adhesion to the nucleation inhibition layer 560. The probability of surface adhesion of the conductive material to the nucleation inhibition layer 560 may be at most 0.3 (or 30%) and at most 0.0008 (or 0.08%) or less. Accordingly, during the nucleation and growth process, the conductive material constituting the intermediate layer 513 may be detached due to low affinity for the nucleation inhibition layer 560 and may not be formed to a set thickness or may only be partially formed. Each of the layers constituting the intermediate layer 513 is formed to be very thin and may affect the nucleation inhibition layer 560 in the following layers. As a result, the entire thickness of the intermediate layer 513 formed on the nucleation inhibition layer 560 is much smaller than the thickness of the intermediate layer 513 formed simultaneously on the areas where the nucleation inhibition layer 560 is not provided (light-emitting portion, and the area between the light-emitting portion and the light-transmitting portion). That is, the second thickness (t2) of the intermediate layer 513 on the light-transmitting portion TA due to the nucleation inhibition layer 560 is much smaller than the first thickness (t1) of the intermediate layer 513 on the bank 530 and the first electrode 511 of the light-emitting portion EA. Accordingly, the intermediate layer 513 in the light-emitting portion TA between the sub-pixels PXL has a very high resistance due to small thickness thereof and thus inhibits flow of current. Therefore, the light-emitting display device of the present disclosure prevents leakage current from flowing through the intermediate layer 513.

FIG. 7 is a cross-sectional view illustrating a light-emitting display deice according to a sixth embodiment of the present disclosure.

Referring to FIG. 7, the light-emitting display device according to the sixth embodiment includes a plurality of thin film transistors TFTs on a substrate 10, a first electrode 511 connected to each of the plurality of thin film transistors TFTs, a light-emitting element 710 including a first electrode 711, an intermediate layer 713, and a second electrode 715, a bank structure including first and second banks 720 and 730 (BK in FIG. 1), a nucleation inhibition layer 760 on the light-transmitting portion TA, and an encapsulation film 170 covering the light-emitting element 710. The light-emitting display device according to the sixth embodiment of the present disclosure includes both the first and second banks 720 and 730 and the nucleation inhibition layer 760, thereby more effectively preventing leakage current from flowing through the intermediate layer 713 between adjacent sub-pixels PXL. The bank 730 includes a first side surface 731, a second side surface 732 opposite the first side surface 731, and an upper surface US between the first side surface 731 and the second side surface 732.

In the light-emitting display device according to the sixth embodiment, the bank structure BK is not limited to the configuration shown in FIG. 7, and any one of the bank structures BK shown in FIGS. 2 to 5 may be selectively provided. That is, the light-emitting display device according to the sixth embodiment has an undercut through the first bank 720 in the bank structure BK adjacent to the light-transmitting portion TA, thereby disconnecting the intermediate layer 713. In addition, by providing the nucleation inhibition layer 760 on the planarization layer 50 of the light-transmitting portion TA, an intermediate layer pattern 713a on the nucleation inhibition layer 760 may be formed to a second thickness t2. The second thickness (t2) of the intermediate layer pattern 713a on the nucleation inhibition layer 760 may be smaller than the first thickness (t1) of the intermediate layer 713 on the first electrode 711 and the bank 730. Accordingly, in the light-emitting display device according to the sixth embodiment, even if the intermediate layer 713 is not disconnected by the first bank 720, the nucleation inhibition layer 760 prevents current from flowing between the intermediate layer 713 and the intermediate layer pattern 713a, thereby leakage current from flowing through the intermediate layer 713. Meanwhile, the intermediate layer pattern 713a contacting the nucleation inhibition layer 760 may be formed as a dummy pattern 750 along with the second electrode 715 in the light-transmitting portion TA.

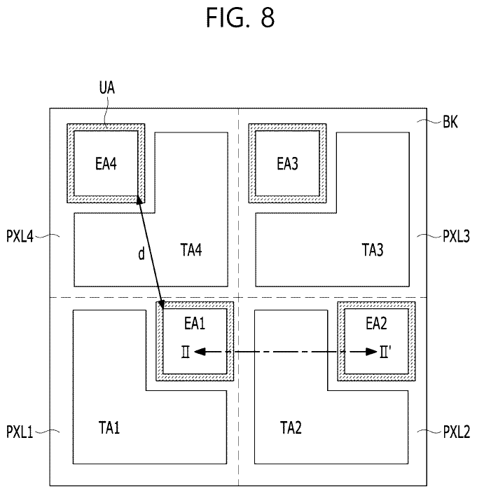

FIG. 8 is a plan view illustrating a light-emitting display device according to a seventh embodiment of the present disclosure. FIG. 9 is a cross-sectional view taken along line II-II′ of FIG. 8.

Referring to FIG. 8, the light-emitting display device according to the seventh embodiment of the present disclosure includes a plurality of sub-pixels including light-emitting portions (EA: EA1, EA2, EA3, and EA4) and light-transmitting portions (TA: TA1, TA2, TA3, and TA4), a bank structure BK exposing the light-emitting portions EA and the light-transmitting portions TA, and an undercut area UA around the light-emitting portion EA. Here, the undercut area UA according to the seventh embodiment may be provided around the light-emitting portion EA.

Additionally, referring to FIG. 9, the light-emitting display device of the present disclosure according to the seventh embodiment includes a plurality of thin film transistors TFTs on a substrate 10, and a first electrode 611 connected to each of the plurality of thin film transistors TFTs, a light-emitting element 610 including a first electrode 611, an intermediate layer 613 and a second electrode 615, a bank 620, and an encapsulation film 170 covering the light-emitting element 610.

At least one unit pixel of the plurality of sub-pixels PXL may include first to fourth sub-pixels PXL1, PXL2, PXL3, and PXL4. The first to fourth sub-pixels PXL1, PXL2, PXL3, and PXL4 may be arranged in a structure of two rows and two columns. The fourth sub-pixel PXL4 may be arranged at the intersection of the first row and the first column, the third sub-pixel PXL3 may be arranged at the intersection of the first row and the second column, the first sub-pixel PXL1 may be arranged at the intersection of the second row and the first column, and the second sub-pixel PXL2 may be arranged at the intersection of the second row and the second column.

The light-emitting display device according to the seventh embodiment may have an increased area of each light-transmitting portion TA compared to the first embodiment. The first to fourth light-transmitting portions TA1, TA2, TA3, and TA4 may be provided along the outer edges of the corresponding first to fourth light-emitting portions EA1, EA2, EA3, and EA4. For example, in the fourth sub-pixel PXL4, the fourth light-transmitting portion TA4 may be provided along the outer edge of the fourth light-emitting portion EA4 in the space between first to third sub-pixels PXL1, PXL2, and PXL3 adjacent to the fourth light-emitting portion EA4. In addition, the third sub-pixel PXL3 may have the same configuration as the fourth sub-pixel PXL4 described above. Meanwhile, the first sub-pixel PXL1 and the second sub-pixel PXL2 may be arranged below the third sub-pixel PXL3 and the fourth sub-pixel PXL4 symmetrical to each other based on the column axis with the third sub-pixel PXL3 and the fourth sub-pixel PXL4. Accordingly, by changing the arrangement structure of the sub-pixel PXL from that of the first embodiment, the light-emitting display device of the present disclosure according to the seventh embodiment has an increased spacing distance (d) between two adjacent light-emitting portions EA compared to the first embodiment. Therefore, in the light-emitting display device according to the seventh embodiment, the path of leakage current can also be increased due to the increased spacing distance d, thereby preventing leakage current from flowing between adjacent sub-pixels PXL.

In addition, in the first to fourth sub-pixels PXL1, PXL2, PXL3, and PXL4, each of the light-emitting portions EA1, EA2, EA3, and EA4 and the corresponding one of the light-transmitting portions TA1, TA2, TA3, and TA4 may be present in an area ratio of 1 to 3. Compared to the first embodiment in which the light-emitting portion EA and the light-transmitting portion TA are at an area ratio of 1 to 1, the light-emitting display device according to the seventh embodiment has an increased transmittance due to an increase in the area of the light-transmitting portion TA.

Referring to FIG. 9, the bank 620 according to the seventh embodiment includes a first side surface 621 having a negative taper shape that exposes the light-emitting portions EA1 and EA2, and a second side surface 622 having a positive taper shape that exposes the light-transmitting portion TA2. The bank 620 according to the seventh embodiment may have a positive taper shape adjacent to the light-emitting portions EA1 and EA2. Accordingly, the path of the intermediate layer 613 between adjacent sub-pixels PXL1 and PXL2 may be increased. Therefore, the bank 620 according to the seventh embodiment increases the path of the intermediate layer 613 between the adjacent light-emitting portions EA1 and EA2 even if separation of the intermediate layer 613 does not occur at the first side surface 621, thereby preventing leakage current from flowing between adjacent sub-pixels PXL1 and PXL2 through the intermediate layer 613.

Additionally, the outer angle θ with respect to the first side surface 621 of the bank 620 may be less than 90°. More specifically, the first side angle θ may be set to 70° or less so that the layer deposited on the top of the bank 620 is disconnected, but the present disclosure is not limited thereto. In consideration of characteristics such as the thickness of the bank 620, the thickness of the intermediate layer 613 deposited on the bank 620, and step coverage, the first side angle θ may be about 70°. Therefore, the bank 620 may separate the intermediate layer 613 between adjacent sub-pixels PXL1 and PXL2.

Meanwhile, the dummy pattern 650 has a negative taper shape of the bank 620 formed on the first side surface 621 adjacent to the light-emitting portions EA1 and EA2, thereby providing the upper surface and the side surface of the bank 620. Therefore, the dummy pattern 650 according to the seventh embodiment may be provided on the top and second side surfaces 622 of the bank 620 and the planarization layer 50 of the light-transmitting portion TA2.

As described above, the light-emitting display device according to the seventh embodiment can minimize contact between the light-emitting portions EA of each of the plurality of sub-pixels PXL through arrangement of the light-transmitting portion TA of each of the plurality of sub-pixels PXL and provision of the negative taper shape of the bank 620 adjacent to the first light-emitting portion EA1 in the light-emitting portion EA. Accordingly, the light-emitting display device according to the seventh embodiment maximizes a path through which leakage current can flow between adjacent sub-pixels PXL even if the intermediate layer 613 is not completely separated by the first side surface 621 having a negative taper shape, thereby providing the effect of preventing light emission in some of the sub-pixels PXL due to leakage current flowing from adjacent sub-pixels.

A light-emitting display device according to one embodiment of present disclosure may comprise a light-transmitting portion between a plurality of light-emitting portions, a first bank exposing each of the light-emitting portions and the light-transmitting portion and an intermediate layer on the light-emitting portions and the first bank.

In a light-emitting display device according to one embodiment of present disclosure, the first bank may have a first side surface adjacent to one of the plurality of light-emitting portions and a second side surface adjacent to the light-transmitting portion.

In a light-emitting display device according to one embodiment of present disclosure, the second side surface may have a negative taper shape.

In a light-emitting display device according to one embodiment of present disclosure, the first side surface may have a positive taper shape.

A light-emitting display device according to one embodiment of present disclosure may further comprises a second bank below the first bank. Side surfaces of the second bank adjacent to one of the plurality of light-emitting portions and the light-transmitting portion may have a positive taper shape.

In a light-emitting display device according to one embodiment of present disclosure, a lower surface between the first side surface and the second side surface of the first bank may be disposed on a side surface of the second bank adjacent to the light-transmitting portion.

In a light-emitting display device according to one embodiment of present disclosure, a vertical distance between the lower surface of the second bank and the first bank may be greater than a thickness of the intermediate layer.

A light-emitting display device according to one embodiment of present disclosure may further comprise a dummy pattern in the light-transmitting portion. The dummy pattern may be disposed on the same layer as at least one layer of layers included in the intermediate layer. The dummy pattern and the intermediate layer may be discontinuous.

In a light-emitting display device according to one embodiment of present disclosure, each of the dummy pattern and the intermediate layer may comprise at least one charge generation layer. The at least one charge generation layer of the dummy pattern may be disposed as a same layer as the at least one charge generation layer of the intermediate layer.

A light-emitting display device according to one embodiment of present disclosure may further comprise a nucleation inhibition layer below the dummy pattern.

In a light-emitting display device according to one embodiment of present disclosure, the dummy pattern may comprise an intermediate layer pattern. A thickness of the intermediate layer pattern may be less than a thickness of the intermediate layer.

In a light-emitting display device according to one embodiment of present disclosure, a lower surface between the first side surface and the second side surface of the first bank may be disposed on an upper surface of the second bank.

In a light-emitting display device according to one embodiment of present disclosure, the lower surface of the first bank may be disposed at an edge of the upper surface adjacent to the light-transmitting portion of the second bank.

In a light-emitting display device according to one embodiment of present disclosure, the first side surface may have a negative taper shape.

A light-emitting display device according to one embodiment of present disclosure, comprise a light-transmitting portion between a plurality of light-emitting portions and a bank structure exposing each of the light-emitting portions and the light-transmitting portion, wherein a side surface of the bank structure adjacent to the light-transmitting portion has a recess.

In a light-emitting display device according to one embodiment of present disclosure, the bank structure comprises a first bank having a first side surface adjacent to one of the plurality of light-emitting portions and a second side adjacent to the light-transmitting portion and a second bank below the first bank. A lower surface between the first side surface and the second side surface of the first bank may be disposed on a side surface of the second bank adjacent to the light-transmitting portion. The recess may be provided between the second side surface of the first bank and the side surface of the second bank.

In a light-emitting display device according to one embodiment of present disclosure, the second side surface of the first bank and the side surface of the second bank may have a positive taper shape.

In a light-emitting display device according to one embodiment of present disclosure, the first bank and the second bank may comprise different materials each other.

A light-emitting display device according to one embodiment of present disclosure may comprise a substrate including a plurality of light-emitting portions and a light-transmitting portion between the light-emitting portions, a bank structure provided on the substrate and exposing each of the light-emitting portions and the light-transmitting portions and a nucleation inhibition layer provided at the light-transmitting portion on the substrate.

In a light-emitting display device according to one embodiment of present disclosure, the nucleation inhibition layer may comprise a polycyclic aromatic compound containing an organic molecule.

A light-emitting display device according to one embodiment of present disclosure may further comprise an intermediate layer on the plurality of light-emitting portions, the bank structure, and the nucleation inhibition layer. A thickness of the intermediate layer on the nucleation inhibition layer may be smaller than a thickness of the intermediate layer on the plurality of light-emitting portions and the bank structure.

As apparent from the foregoing, the light-emitting display device of the present disclosure has the following effects.

First, the light-emitting display device of the present disclosure minimizes contact between the light-emitting portions of each of the plurality of sub-pixels through arrangement of the light-transmitting portion of each of the plurality of sub-pixels, thereby maximizing the path through which leakage current can flow between adjacent sub-pixels. Accordingly, the light-emitting display device of the present disclosure has the effect of preventing light emission in some of a plurality of sub-pixels due to leakage current flowing from adjacent sub-pixels.

Second, the light-emitting display device of the present disclosure can prevent some of a plurality of sub-pixels from emitting light due to leakage current flowing from adjacent sub-pixels based on an undercut area adjacent to the light-transmitting portion, and at the same time, can prevent deterioration and lifespan reduction of the light-emitting element based on uniform deposition of the intermediate layer formed in the light-emitting portion.

Third, the light-emitting display device of the present disclosure has a nucleation inhibition layer in the light-transmitting portion to adjust the thickness of the intermediate layer deposited on the nucleation inhibition layer to a small level, thereby preventing leakage current from flowing to adjacent sub-pixels through the intermediate layer.

Fourth, the light-emitting display device of the present disclosure provides an undercut area in the transparent portion, thereby preventing leakage current from flowing between adjacent sub-pixels, and deterioration and reduction in lifespan of the light-emitting element, and reducing power consumption and energy required for production. Accordingly, the light-emitting display device of the present disclosure has ESG (environment/social/governance) effects in terms of eco-friendliness, low power consumption, and process optimization.

It will be apparent to those skilled in the art that various modifications and variations can be made in the disclosure without departing from the spirit or scope of the disclosure. Thus, it is intended that the disclosure cover such modifications and variations thereof, provided they fall within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light-emitting display device comprising:
a light-transmitting portion between a plurality of light-emitting portions;
a first electrode at each of the plurality of light-emitting portions;
a first bank exposing each of the light-emitting portions and the light-transmitting portion;
an intermediate layer on the light-emitting portions and the first bank; and
a second electrode on the intermediate layer,
wherein the first bank has a first side surface adjacent to one of the plurality of light-emitting portions and a second side surface adjacent to the light-transmitting portion, and
wherein the second side surface has a negative taper shape.

2. The light-emitting display device of claim 1,
wherein the bank structure includes an upper surface between the first side surface and the second side surface,
wherein the first side surface and the second side surface are inclined in a first direction, and
wherein the first side surface overlaps a part of the first electrode.

3. The light-emitting display device according to claim 1, wherein the first side surface has a positive taper shape.

4. The light-emitting display device of claim 1,
wherein the bank structure includes an upper surface between the first side surface and the second side surface,
wherein the first side surface is inclined in a first direction, and the second side surface is inclined in a second direction transverse to the first direction, and
wherein the first side surface overlaps the first electrode.

5. The light-emitting display device according to claim 1, further comprising a second bank adjacent to the first bank,
wherein side surfaces of the second bank adjacent to one of the plurality of light-emitting portions and the light-transmitting portion have a positive taper shape.

6. The light-emitting display device according to claim 5, wherein a lower surface between the first side surface and the second side surface of the first bank is disposed on a side surface of the second bank adjacent to the light-transmitting portion.

7. The light-emitting display device according to claim 5, wherein a vertical distance between a lower surface of the second bank and the first bank is greater than a thickness of the intermediate layer.

8. The light-emitting display device according to claim 7, further comprising a dummy pattern in the light-transmitting portion,
wherein the dummy pattern is disposed as a same layer as at least one layer of layers included in the intermediate layer, and
wherein the dummy pattern and the intermediate layer are discontinuous.

9. The light-emitting display device according to claim 8, wherein each of the dummy pattern and the intermediate layer comprises at least one charge generation layer, and
wherein the at least one charge generation layer of the dummy pattern is disposed as a same layer as the at least one charge generation layer of the intermediate layer.

10. The light-emitting display device according to claim 8, further comprising a nucleation inhibition layer below the dummy pattern.

11. The light-emitting display device according to claim 10, wherein the dummy pattern comprises an intermediate layer pattern, and
wherein a thickness of the intermediate layer pattern is less than a thickness of the intermediate layer.

12. The light-emitting display device according to claim 5, wherein a lower surface between the first side surface and the second side surface of the first bank is disposed on an upper surface of the second bank.

13. The light-emitting display device according to claim 12, wherein the lower surface of the first bank is disposed at an edge of the upper surface adjacent to the light-transmitting portion of the second bank.

14. The light-emitting display device according to claim 6, wherein the first side surface has a negative taper shape.

15. A light-emitting display device comprising:
a light-transmitting portion between a plurality of light-emitting portions;
a light-emitting elements including a first electrode, a second electrode and an intermediate layer between the first electrode and the second electrode at each of the light-emitting portion; and
a bank structure exposing each of the light-emitting portions and the light-transmitting portion,
wherein one side surface of the bank structure overlaps a part of a first electrode and the other side surface of the bank structure adjacent to the light-transmitting portion has a recess.

16. The light-emitting display device according to claim 15, wherein the bank structure comprises:
a first bank having a first side surface adjacent to one of the plurality of light-emitting portions and a second side surface adjacent to the light-transmitting portion; and
a second bank adjacent to the first bank,
wherein a lower surface between the first side surface and the second side surface of the first bank is disposed on a side surface of the second bank adjacent to the light-transmitting portion, and
wherein the recess is provided between the second side surface of the first bank and the side surface of the second bank.

17. The light-emitting display device according to claim 16, wherein the second side surface of the first bank and the side surface of the second bank have a positive taper shape.

18. The light-emitting display device according to claim 16, wherein the first bank and the second bank comprise different materials from each other.

19. A light-emitting display device comprising:
a substrate including a plurality of light-emitting portions and a light-transmitting portion between the light-emitting portions;
a light-emitting elements including a first electrode, a second electrode and an intermediate layer between the first electrode and the second electrode at each of the light-emitting portion;
a bank structure provided overlapping a part of the first electrode and exposing each of the light-emitting portions and the light-transmitting portions; and
a nucleation inhibition layer provided at the light-transmitting portion on the substrate.

20. The light-emitting display device according to claim 19, wherein the nucleation inhibition layer comprises a polycyclic aromatic compound containing an organic molecule.

21. The light-emitting display device according to claim 19, further comprising an intermediate layer on the plurality of light-emitting portions, the bank structure, and the nucleation inhibition layer,
wherein a thickness of the intermediate layer on the nucleation inhibition layer is smaller than a thickness of the intermediate layer on the plurality of light-emitting portions and the bank structure.

22. A light-emitting display device comprising:
a light-emitting element including a first electrode, a second electrode, and an intermediate layer between the first electrode and the second electrode;
a bank structure adjacent to the light-emitting element, the bank structure having a first side surface, a second side surface opposite the first side surface, and an upper surface between the first side surface and the second side surface;
a thin film transistor electrically connected to the light-emitting element, the thin film transistor overlapping the light-emitting element; and
a light-transmitting portion adjacent to the second side surface of the bank structure,
wherein the intermediate layer is on the upper surface of the bank structure and discontinuous between the second side surface of the bank structure and the light-transmitting portion.

23. The light-emitting display device of claim 22, wherein the first side surface and the second side surface are inclined in a first direction.

24. The light-emitting display device of claim 23,
wherein either the intermediate layer or the second electrode continuously and contiguously extends from the light-emitting element to the upper surface of the bank structure and wherein either the intermediate layer or the second electrode directly contacts the first side surface of the bank structure.

25. The light-emitting display device of claim 23, further comprising:
a dummy pattern adjacent to the bank structure, the dummy pattern including the intermediate layer and the second electrode,
wherein the intermediate layer of the dummy pattern is spaced apart from the intermediate layer on the upper surface of the bank structure.

26. The light-emitting display device of claim 25, wherein the second electrode of the dummy pattern is spaced apart from the second side surface of the bank structure.

27. The light-emitting display device of claim 22, wherein the first side surface is inclined in a first direction, and the second side surface is inclined in a second direction transverse to the first direction.

28. The light-emitting display device of claim 27, further comprising a second bank structure on either the upper surface of the bank structure or the second side surface of the bank structure,
wherein the second bank structure includes a first side surface, a second side surface opposite the first side surface, a lower surface between the first side surface and the second side surface, and wherein the lower surface of the second bank structure directly contacts either the upper surface of the bank structure or the second side surface of the bank structure.

29. The light-emitting display device of claim 28, wherein either the intermediate layer or the second electrode continuously and contiguously extends from the light-emitting element to the upper surface of the bank structure and the first side surface of the second bank structure.

30. The light-emitting display device of claim 28, wherein either the intermediate layer or the second electrode directly contacts the first side surface of the second bank structure.

31. The light-emitting display device of claim 28, wherein either the intermediate layer or the second electrode is not in contact with the second side surface of the second bank structure.

32. The light-emitting display device of claim 28, further comprising:
a dummy pattern adjacent to the second bank structure, the dummy pattern including the intermediate layer and the second electrode,
wherein at least one the intermediate layer and the second electrode of the dummy pattern is spaced apart from the second side surface of the bank structure and the second side surface of the second bank structure.
